(19) United States
(12) Patent Application Publication
(10) Pub. No.: US 2025/0143112 A1
(43) Pub. Date: May 1, 2025

(54) DISPLAY SUBSTRATE AND MANUFACTURING METHOD THEREOF

(71) Applicant: BOE Technology Group Co., Ltd., Beijing (CN)

(72) Inventors: Dapeng XUE, Beijing (CN); Yingwei LIU, Beijing (CN); Ke WANG, Beijing (CN); Zhanfeng CAO, Beijing (CN)

(21) Appl. No.: 18/692,796

(22) PCT Filed: Jul. 31, 2023
(86) PCT No.: PCT/CN2023/110090

§ 371 Date: Mar. 15, 2024

(30) Foreign Application Priority Data
Aug. 24, 2022 (CN) 202211016718.0

(51) Int. Cl. H10K 59/131; H10K 59/12

(52) U.S. Cl. CPC H10K 59/131; H10K 59/1201

(57) ABSTRACT

Disclosed are a display substrate. The display substrate of the present disclosure includes a base substrate, a pixel drive circuit, and a connection structure. The base substrate is provided with a connection via hole penetrating in a thickness direction of the base substrate, and the base substrate includes a first surface and a second surface disposed oppositely along the thickness direction of the base substrate; the pixel drive circuit is disposed on the first surface; the signal wiring is disposed on the second surface; and the connection structure is disposed in the connection via hole and electrically connects the signal wiring with the pixel drive circuit. The connection via hole is partially filled by the connection structure.

### CROSS-REFERENCE TO RELATED APPLICATION

This application is a U.S. national stage of international application No. PCT/CN2023/110090, filed on Jul. 31, 2023, which claims priority to Chinese Patent Application No. 202211016718.0, filed on Aug. 24, 2022, and entitled “DISPLAY SUBSTRATE AND PREPARATION METHOD THEREOF”, the disclosures of which are herein incorporated by reference in their entireties.

### TECHNICAL FIELD

The present disclosure relates to the field of display technologies, and in particular, relates to a display substrate and a method for manufacturing the same.

### BACKGROUND

With the development of integrated circuit technology, the calls for the end of Moore's Law have grown louder. Planar integrated circuits are facing serious challenges, and the emergence of 2.5D integration technology extends the integration space to a third dimension, which significantly improves the utilization of space. Compared with the traditional planar integration technology, 2.5D integration technology transmits signals through a vertical interconnection structure, and has the advantages of a high integration level, low power consumption, flexible design, easiness in achieving heterogeneous integration, etc.

### SUMMARY

Some embodiments of the present disclosure provide a display substrate. The display substrate includes a base substrate, a pixel drive circuit, a signal wiring, and a connection structure.

T base substrate is provided with a connection via hole penetrating in a thickness direction of the base substrate, and the base substrate includes a first surface and a second surface disposed oppositely along the thickness direction of the base substrate.

The pixel drive circuit is disposed on the first surface.

The signal wiring is disposed on the second surface; and
the connection structure disposed in the connection via hole and electrically connecting the signal wiring with the pixel drive circuit, wherein the connection via hole is partially filled by the connection structure.

In some embodiments, the connection structure includes a first substructure disposed on a sidewall of the connection via hole and a second substructure connected to the first substructure, with an outer outline of the second substructure fitted to the first substructure.

In some embodiments, the second substructure includes a third surface and a fourth surface disposed oppositely along a thickness direction of the second substructure; the third surface is flush with the first surface, and a certain distance is reserved between a plane where the fourth surface is located and a plane where the second surface is located; or, the fourth surface is flush with the second surface, and a certain distance is reserved between a plane where the third surface is located and a plane where the first surface is located; or, a certain distance is reserved between the plane where the third surface is located and the plane where the first surface is located, and a certain distance is reserved between the plane where the fourth surface is located and the plane where the second surface is located.

In some embodiments, the second substructure includes a first portion and a second portion, with an outer outline of the first portion and an outer outline of the second portion both fitted to the first substructure and a certain distance reserved between the first portion and the second portion.

In some embodiments, a surface of the first portion distal to the second portion is flush with the first surface; and a surface of the second portion distal to the first portion is flush with the second surface.

In some embodiments, the second substructure includes a third surface and a fourth surface disposed oppositely along a thickness direction of the second substructure; the third surface is an arc surface and protrudes towards the fourth surface; and/or the fourth surface is an arc surface and protrudes towards the third surface.

In some embodiments, the second substructure includes a third surface and a fourth surface disposed oppositely along a thickness direction of the second substructure; the third surface is folded and protrudes towards the fourth surface; and/or the fourth surface is folded and protrudes towards the third surface.

In some embodiments, the connection structure is disposed in the connection via hole to define an accommodating space with a filling structure filled therein.

In some embodiments, a first protection layer is covered on a sidewall of the connection via hole, and the first protection layer is disposed between the sidewall of the connection via hole and the connection structure.

In some embodiments, a connection pad is further disposed on the second surface, and the signal wiring is electrically connected to the connection structure through the connection pad.

Some embodiments of the present disclosure provide a method for manufacturing a display substrate. The method includes the following steps.

A base substrate is provided, wherein a connection via hole penetrating in a thickness direction of the base substrate is formed thereon; the base substrate includes a first surface and a second surface disposed oppositely along the thickness direction of the base substrate;

A connection structure is formed in the connection via hole of the base substrate, forming a pixel drive circuit on the first surface of the base substrate, and forming a signal wiring on the second surface of the base substrate, with the connection structure electrically connecting the signal wiring with the pixel drive circuit, wherein the connection structure does not fill the connection via hole completely.

In some embodiments, the connection structure includes a first substructure disposed on a sidewall of the connection via hole and a second substructure connected to the first substructure; and the connection structure is formed by:
forming a first conductive thin film on the first surface, the second surface, and the sidewall of the connection via hole of the base substrate to serve as a seed layer, and performing electroplating and patterning processes in sequence to form the connection structure, wherein the seed layer disposed on the sidewall of the connection via hole serves as the first substructure, a structure of the seed layer disposed in the connection via hole and connected to the first substructure, serves as the second substructure.

In some embodiments, the second substructure includes a third surface and a fourth surface disposed oppositely along a thickness direction of the second substructure; the third surface is flush with the first surface, and a certain distance is reserved between a plane where the fourth surface is located and a plane where the second surface is located; or, the fourth surface is flush with the second surface, and a certain distance is reserved between a plane where the third surface is located and a plane where the first surface is located; or, a certain distance is reserved between the plane where the third surface is located and the plane where the first surface is located, and a certain distance is reserved between the plane where the fourth surface is located and the plane where the second surface is located.

In some embodiments, the second substructure includes a first portion and a second portion, with an outer outline of the first portion and an outer outline of the second portion both fitted to the first substructure and a certain distance reserved between the first portion and the second portion.

In some embodiments, a surface of the first portion distal to the second portion is flush with the first surface; and a surface of the second portion distal to the first portion is flush with the second surface.

In some embodiments, the second substructure includes a third surface and a fourth surface disposed oppositely along a thickness direction of the second substructure; the third surface is an arc surface and protrudes towards the fourth surface; and/or the fourth surface is an arc surface and protrudes towards the third surface.

In some embodiments, the second substructure includes a third surface and a fourth surface disposed oppositely along a thickness direction of the second substructure; the third surface is folded and protrudes towards the fourth surface; and/or the fourth surface is folded and protrudes towards the third surface.

In some embodiments, the manufacturing method further includes filling a filling structure in an accommodating space defined by forming the connection structure in the connection via hole.

In some embodiments, the manufacturing method further includes forming a first protection layer on at least a sidewall of the connection via hole before forming the connection via hole.

In some embodiments, the manufacturing method further includes forming a connection pad on the second surface, wherein the signal wiring is electrically connected to the connection structure through the connection pad.

### BRIEF DESCRIPTION OF THE DRAWINGS

FIG. 1 is a schematic diagram of a display substrate according to some embodiments of the present disclosure;

FIG. 2 is a schematic diagram of an intermediate product formed in step S11 of the first example according to some embodiments of the present disclosure;

FIG. 3 is a schematic diagram of an intermediate product formed in step S12 of the first example according to some embodiments of the present disclosure;

FIG. 4 is a schematic diagram of an intermediate product formed in step S13 of the first example according to some embodiments of the present disclosure;

FIG. 5 is a schematic diagram of an intermediate product formed in step S14 of the first example according to some embodiments of the present disclosure;

FIG. 6 is a schematic diagram of an intermediate product formed in step S15 of the first example according to some embodiments of the present disclosure;

FIG. 7 is a schematic diagram of an intermediate product formed in step S16 of the first example according to some embodiments of the present disclosure;

FIG. 8 is a schematic diagram of an intermediate product formed in step S17 of the first example according to some embodiments of the present disclosure;

FIG. 9 is a partial schematic diagram of the display substrate of the second example according to some embodiments of the present disclosure;

FIG. 10 is a partial schematic diagram of the display substrate of the third example according to some embodiments of the present disclosure;

FIG. 11 is a partial schematic diagram of the display substrate of the fourth example according to some embodiments of the present disclosure;

FIG. 12 is a partial schematic diagram of the display substrate of the fifth example according to some embodiments of the present disclosure; and

FIG. 13 is a partial schematic diagram of the display substrate of the sixth example according to some embodiments of the present disclosure.

### DETAILED DESCRIPTION

To enable those skilled in the art to better understand the technical solutions of the present disclosure, the present disclosure is further described in detail below with reference to the accompanying drawings and specific embodiments.

Unless otherwise defined, technical or scientific terms used in the present disclosure should have ordinary meanings as understood by those of ordinary skill in the art to which the present disclosure belongs. The terms “first”, “second”, and other similar words, as used in the present disclosure do not indicate any order, quantity, or importance, but are merely defined to distinguish different components. Likewise, the terms “a”, “an”, “the”, or other similar words do not indicate a limitation of quantity, but rather the presence of at least one. The terms “include”, “comprise”, or other similar words indicate that the elements or objects stated before them encompass the elements or objects and equivalents thereof listed after them, but do not exclude other elements or objects. The terms “connecting”, “connected”, or other similar words are not limited to physical or mechanical connections, but may include electrical connections, whether direct or indirect. The terms “up”, “down”, “left”, “right”, and the like are merely defined to indicate relative positional relationships. In the case that the absolute position of a described object changes, the relative position relationship may also change accordingly.

The embodiments of the present disclosure provide a display substrate, which includes a base substrate 10, a pixel drive circuit, a signal wiring 21, and a connection structure 23. A connection via hole 11 penetrating in the thickness direction of the base substrate 10 is formed thereon. The base substrate 10 includes a first surface s1 and a second surface s2 disposed oppositely along the thickness direction thereof. The pixel drive circuit is disposed on the first surface s1 of the base substrate 10, the signal wiring 21 is disposed on the second surface s2 of the base substrate 10, and the connection structure 23 is disposed in the connection via hole 11. The signal wiring 21 provides a drive signal for the pixel drive circuit through the connection structure 23, that is, the signal wiring 21 is electrically connected to the pixel drive circuit through the connection structure 23. Particularly, according to the embodiments of the present disclosure, the connection via hole 11 is only partially filled by the connection structure 23, that is, the connection structure 23 does not fill the connection via hole 11 completely, which mitigates the sidewall burrs of the connection via hole 11 as well as the thermal stress impact caused by the different materials and mismatched thermal expansion coefficients between the base substrate 10 and the connection structure 23, thereby improving the yield and reliability of the manufactured display substrate.

It should be noted that the connection via hole 11 is partially filled by the connection structure 23, and it is necessary to ensure that the outer outline of the connection structure 23 abuts against the sidewall of the connection via hole 11. In the case that the connection structure 23 is a one-piece structure, the connection structure is solid; in the case that the connection structure 23 is a separated structure (i.e., including a plurality of components), each part of the connection structure 23 is a solid structure, and the outer outline of each part of the connection structure 23 abuts against the sidewall of the connection via hole 11.

In some embodiments, the display substrate according to the embodiments of the present disclosure is applicable to a liquid crystal display panel, an organic electroluminescent diode display panel, and multi-zone independently controlled luminescent diode backlighting.

Further, in the case that the display substrate is applicable to a liquid crystal display panel, the display substrate includes not only the structure described above but also gate lines and data lines disposed on the first surface s1 of the base substrate 10. The gate lines and data lines intersect to define a plurality of pixel units, and each pixel unit includes a pixel drive circuit and a pixel electrode. The pixel drive circuit includes a thin-film transistor. The gate of the thin-film transistor is connected to the gate line, the source of the thin-film transistor is connected to the data line, and the drain of the thin-film transistor is connected to the pixel electrode. For example, in the case that the electric field mode of the display panel is a transverse electric field, a common electrode is further disposed in each pixel unit. A voltage is applied to the pixel electrode and the common electrode to form an electric field to drive liquid crystal molecules in the display panel to deflect, such that the display of the corresponding gray scale of each pixel unit is achieved.

In the case that the display substrate is applicable to the organic electroluminescent diode display panel, the display substrate not only includes the structure described above but also gate lines and data lines disposed on the first surface s1 of the base substrate 10. The gate lines and data lines intersect to define a plurality of pixel units, and each pixel unit includes a pixel drive circuit and an organic electroluminescent diode electrically connected to the pixel drive circuit. The pixel drive circuit is a typical 2T1C (two thin-film transistors and one storage capacitor), 7T1C (seven thin-film transistors and one storage capacitor), and the like. Each pixel drive circuit is connected to a corresponding gate line and a corresponding data line. The working state of the pixel drive circuit is controlled through the switching voltage written on the gate line, and the organic electroluminescent diode is controlled through the magnitude of the data voltage applied on the data line, such that the display of different gray scales is achieved.

In the case that the display substrate is applicable to multi-zone independently controlled luminescent diode backlighting, the display substrate not only includes the structure described above but also gate lines and data lines disposed on the first surface s1 of the base substrate 10. The gate lines and data lines intersect to define a plurality of pixel units, and each pixel unit includes a pixel drive circuit and a multi-zone independently controlled luminescent diode electrically connected to the pixel drive circuit. The pixel drive circuit includes a thin-film transistor. The gate of the thin-film transistor is connected to the gate line, the source of the thin-film transistor is connected to a data line, and the drain of the thin-film transistor is connected to the anode of the multi-zone independently controlled luminescent diode. The working state of the thin-film transistor is controlled through the switching voltage written on the gate line, and whether the multi-zone independently controlled luminescent diode is lightened or not is controlled by the magnitude of the data voltage applied on the data line, such that the local dimming of the display panel is achieved.

In the embodiments of the present disclosure, the display substrate is not limited to the three types described above, and the foregoing is only an exemplary illustration and does not limit the protection scope of the embodiments of the present disclosure. In addition, FIG. 1 is only an example of a display substrate with multi-zone independently controlled luminescent diodes. In FIG. 1, for example, a thin-film transistor in a pixel drive circuit is a bottom-gate-type thin-film transistor. A gate insulating layer 60 is disposed between the active layer and the gate of the thin-film transistor, a first signal line 102 is further disposed on the layer where the gate of the thin-film transistor is located, and a second signal line 103 is further disposed on the layer where the source and the drain of the thin-film transistor are located. The first signal line 102 and the second signal line 103 are electrically connected through a via hole penetrating through the gate insulating layer 60, and the first signal line is electrically connected to the connection structure 23. The first signal line and the second signal line are electrically connected for transmitting the control signal inputted by the signal wiring 21 to the pixel drive circuit. With reference to FIG. 1 still, a first interlayer insulating layer 70 is disposed on the layer where the source and the drain of the thin-film transistor are located, and a first power terminal VDD, a second power terminal VSS, and a transfer electrode 101 are disposed on the first interlayer insulating layer 70. The first power terminal VDD is connected to the source of the thin-film transistor through a via hole penetrating through the first interlayer insulating layer 70, and the transfer electrode 101 is connected to the drain of the thin-film transistor through a via hole penetrating through the first interlayer insulating layer 70. A second interlayer insulating layer 80 and a third interlayer insulating layer 90 are disposed sequentially on the first power terminal VDD, the second power terminal VSS, and the transfer electrode 101. The anode of the light-emitting device 100 is electrically connected to the transfer electrode 101 through a via hole penetrating through the second interlayer insulating layer 80 and the third interlayer insulating layer 90, and the cathode of the light-emitting device 100 is electrically connected to the second power terminal VSS through another via hole penetrating through the second interlayer insulating layer 80 and the third interlayer insulating layer 90.

In some embodiments, the connection structure 23 is formed by an electroplating process, and the connection structure 23 is made of metal copper. A first conductive thin film 20 is formed on the sidewall of the connection via hole 11 as a seed layer, and the first conductive thin film 20 is made of copper. Then, by placing the base substrate 10 in an electroplating solution containing copper ions, an electroplating process is used to fill copper in the connection via hole 11 and thicken the copper on the surface, thus forming the connection structure 23. It can be seen that the connection structure 23 disposed in the connection via hole 11 includes two parts, with one part being a first substructure 231, i.e., a seed layer, disposed on the sidewall of the connection via hole 11 and the other part being a structure grown thicker on the seed layer through an electroplating process, i.e., a second substructure 232. As the structure is formed through the electroplating process, the first substructure 231 and the second substructure 232 are connected into an integral structure.

In some embodiments, a first protection layer 30 is disposed between the first substructure 231 of the connection structure 23 and the sidewall of the connection via hole 11 to protect the sidewall of the connection via hole 11. In addition, the first protection layer 30 covers the first surface s1 and the second surface s2 of the base substrate 10 to avoid damaging the first surface s1 and the second surface s2 of the base substrate 10 when forming an electrical device on the first surface s1 and the second surface s2 of the base substrate 10 subsequently.

In some embodiments, the connection structure 23 is formed by electroplating in the embodiments of the present disclosure. The display substrate according to the embodiments of the present disclosure is described in detail with reference to the following specific examples.

In the first example, as shown in FIG. 1, the connection structure 23 in the display substrate includes the first substructure 231 and the second substructure 232. The first substructure 231 is disposed on the sidewall of the connection via hole 11 of the base substrate 10, and the outer outline of the second substructure 232 is fitted to and connected to the first substructure 231 as an integral structure. The second substructure 232 includes a third surface s3 and a fourth surface s4 disposed oppositely along the thickness direction thereof. The third surface s3 of the second substructure 232 is flush with the first surface s1 of the base substrate 10, with a certain distance reserved between the plane where the fourth surface s4 of the second substructure 232 is located and the plane where the second surface s2 of the base substrate 10 is located. It should be noted that, in the case that the first protection layer 30 covers the first surface s1, the third surface s3 of the second substructure 232 is flush or substantially flush with the first protection layer 30 disposed on the first surface s1 of the base substrate 10.

In some embodiments, a connection pad 22 is further formed on the second surface s2 of the base substrate 10, and the connection pad 22 is connected to the first connection structure 23 through the signal wiring 21. In this way, after a drive chip is bonded to the connection pad 22, a drive signal is provided to the pixel drive circuit. Further, the signal wiring 21 and the connection pad 22 are formed into an integral structure, and still further, the signal wiring 21, the connection pad 22, and the connection structure 23 are formed into an integral structure. For example, the signal wiring 21, the connection pad 22, and the first substructure 231 of the connection structure 23 are formed into an integral structure, that is, a first conductive layer (seed layer) is formed on the base substrate 10, and after the second substructure 232 is formed by electroplating, patterning is performed on the first conductive layer on the second surface s2 of the base substrate 10, such that the signal wiring 21 and the connection pad 22 that are electrically connected to the first substructure 231 is formed.

In some embodiments, as a certain distance exists between the plane of the fourth surface s4 of the second substructure 232 and the plane of the second surface s2 of the base substrate 10, the connection structure 23 is disposed in the connection via hole 11 to define an accommodating space 111 (the remaining space in the connection via hole 11 in addition to the connection structure 23). The accommodating space 111 is filled with a filling structure 40. The filling structure 40 is made of a resin material, and the filling structure 40 not only serves as a support, but also prevents oxidization of the connection structure 23.

Further, while forming the filling structure 40 disposed in the accommodating space 111, a second protection layer 50 is further formed on a side of the signal wiring 21 distal to the base substrate 10 to prevent corrosion of the signal wiring 21. It should be understood that the second protection layer 50 exposes the connection pad 22 as the connection pad 22 needs to be bonded to the drive chip.

In some embodiments, as the connection structure 23 is formed using an electroplating process, the first protection layer 30 is formed between the side of the connection structure 23 and the connection via hole 11 to protect the sidewall of the connection via hole 11. The material of the first protection layer 30 includes, but is not limited to, aluminum oxide, silicon oxide, and the like.

With respect to the display substrate shown in FIG. 1, a method for manufacturing the display substrate is provided below. With reference to FIGS. 1 to 8, the method for manufacturing the display substrate includes the following steps.

In S11, a base substrate 10 is provided. A connection via hole 11 penetrating in the thickness direction of the base substrate is formed thereon. The base substrate 10 includes a first surface s1 and a second surface s2 disposed oppositely along the thickness direction thereof. FIG. 2 is a schematic diagram of an intermediate product formed in step S11 of the first example according to some embodiments of the present disclosure.

In some embodiments, the base substrate 10 includes, but is not limited to, a glass substrate. In the embodiments of the present disclosure, a glass substrate is exemplified as the base substrate 10. S11 includes the step of forming the connection via hole 11 by a sandblasting method, a photosensitive glass method, a focused discharge method, a plasma etching method, a laser ablation method, an electrochemical method, a laser-induced etching method, or the like.

The following describes a process of forming the connection via hole 11 by a laser-induced etching method as an example.
(1) Cleaning: A glass substrate was washed in a cleaning machine.

In some embodiments, the glass substrate has a thickness of about 0.1 mm to 1.1 mm.
(2) Laser drilling: A laser device is used to drill the glass substrate surface with vertically incident laser beams to form a plurality of connection via holes 11 on the glass substrate. Specifically, when the laser beams interact with the glass substrate, the atoms in the glass substrate are ionized and ejected out of the surface of the glass substrate due to the higher energy of the laser photons, and the drilled holes are gradually deepened along with the increase of time until the whole glass substrate is drilled through, namely, a plurality of connection via hole 11 are formed. The commonly selected laser wavelength includes 532 nm, 355 nm, 266 nm, 248 nm, 197 nm, etc., the pulse width of the laser is selected from 1-100 fs, 1-100 ps, 1-100 ns, etc., and the type of the laser device is selected from a continuous laser, a pulse laser, etc. The laser drilling method includes, but is not limited to, the following two methods. In the first method, in the case that the diameter of the light spot is larger, the relative position of a laser beam and a glass substrate is fixed, and the glass substrate is directly drilled through by high energy. In this case, the shape of the formed connection via hole 11 is an inverted circular truncated cone whose diameter is sequentially reduced from top to bottom (from the second surface s2 to the first surface s1). In the second method, in the case that the diameter of the light spot is small, a laser beam draws a circle on a glass substrate for scanning, and the focus point of the light spot is constantly changed. In addition, the depth of the focus point is constantly changed, and a spiral line is drawn from the lower surface (first surface s1) of the glass substrate to the upper surface (second surface s2) of the glass substrate. The radius of the spiral is sequentially reduced from bottom to top, therefore the glass substrate is cut into a circular truncated cone by laser. The circular truncated cone falls due to gravity, such that the connection via hole 11 is formed, with a shape of a circular truncated cone.

In some embodiments, the connection via hole 11 is formed with an aperture in the range of about 10 μm to 1 mm.
(3) HF etching: As a stress region is formed on the surface of the inner wall of the connection via hole 11 within about 5-20 micrometers near the hole during the laser drilling process. The glass substrate surface in the region is uneven and presents a molten state with a plurality of burrs. Additionally, there are numerous micro-cracks and macro-cracks, along with residual stress. In this case, wet etching is performed using 2%-20% of HF etching liquid for a certain period of time at a proper temperature. The glass in the stress area is etched away to make the inside and the surface region near the hole of the connection via hole 11 smooth and flat without micro-cracks and macro-cracks. The stress region is completely etched away.

In S12, the first protection layer 30 is formed on the first surface s1 and the second surface s2 of the base substrate 10 as well as the sidewall of the connection via hole 11. FIG. 3 is a schematic diagram of an intermediate product formed in step S12 of the first example according to some embodiments of the present disclosure.

In some embodiments, atomic layer deposition (ALD) method is adopted in step S12 to form a first protection layer 30 covering the first surface s1 and the second surface s2 of the base substrate 10, and the first protection layer is also formed on the sidewall of the connection via hole 11 to protect the sidewall of the connection via hole 11. The material of the first protection layer 30 includes, but is not limited to, aluminum oxide or silicon oxide, and the like.

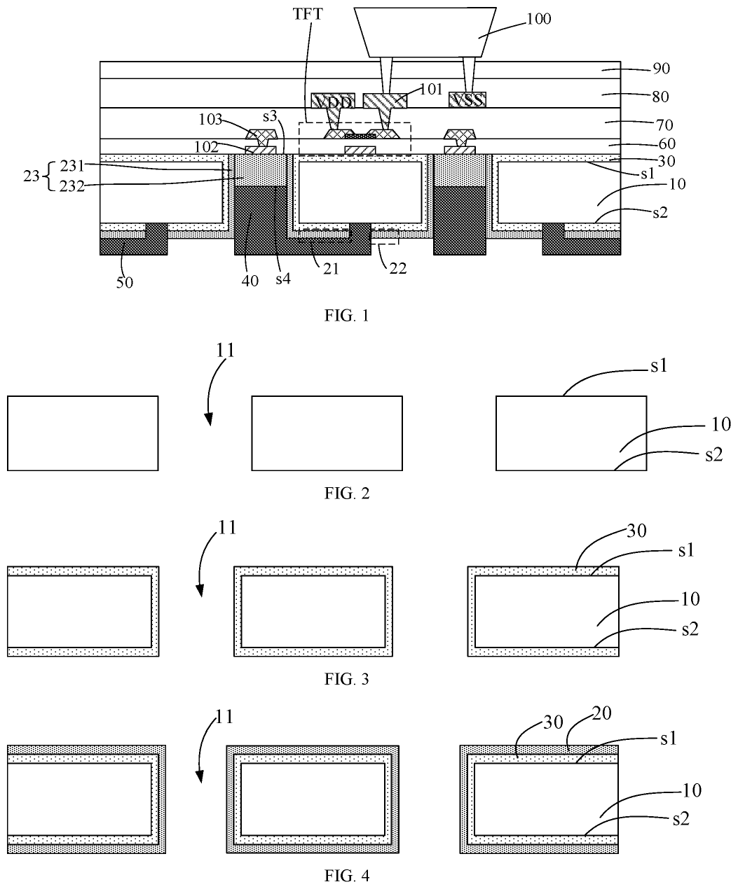

In S13, the first conductive thin film 20 is formed on the first surface s1 and the second surface s2 of the base substrate 10 as well as the sidewall of the connection via hole 11 on which the first protection layer 30 has been formed. The first conductive layer serves as a seed layer for forming the connection structure 23. FIG. 4 is a schematic diagram of an intermediate product formed in step S13 of the first example according to some embodiments of the present disclosure.

In some embodiments, magnetron sputtering is adopted in step S13 to deposit the first conductive thin film 20 on the first surface s1 of the base substrate 10 as a seed layer. During such process, the first conductive thin film 20 is further deposited on the sidewall of the connection via hole 11. Then, the base substrate 10 is turned over, and likewise, the first conductive thin film 20 is formed on the second surface s2 of the base substrate 10 by adopting magnetron sputtering, and the first conductive thin film 20 on the second surface s2 also serves as a seed layer.

In some embodiments, the material of the first conductive thin film 20 includes, but is not limited to, at least one of copper (Cu), aluminum (Al), molybdenum (Mo), and silver (Ag).

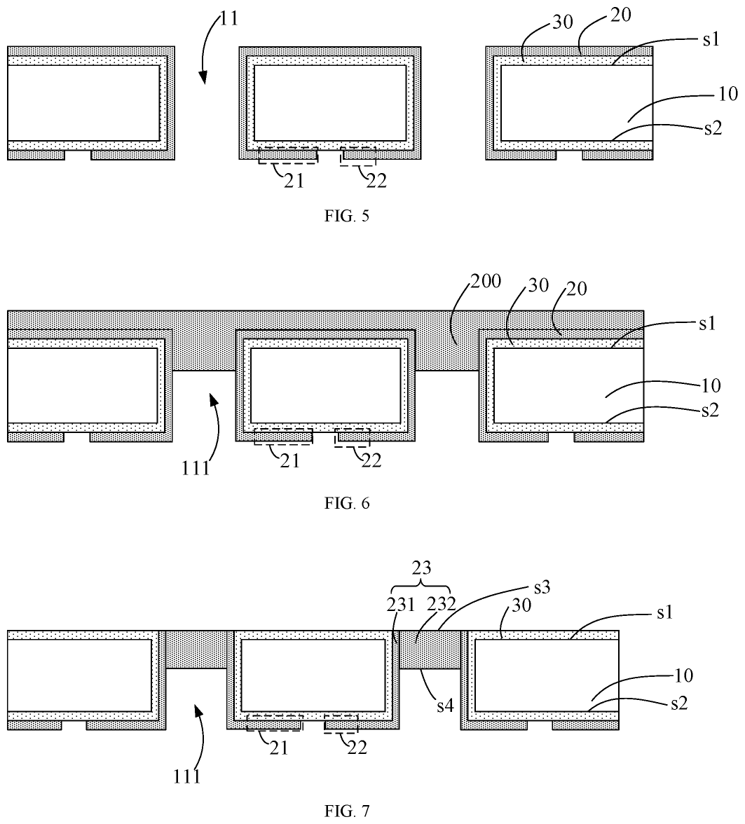

In S14, the signal wiring 21 and the connection pad 22 are formed through a patterning process. FIG. 5 is a schematic diagram of an intermediate product formed in step S14 of the first example according to some embodiments of the present disclosure.

In some embodiments, step S14 includes coating a photoresist on the second surface s2 of the base substrate 10, and then forming the signal wiring 21 and the connection pad 22 by exposure, development, and etching.

In S15, the first conductive thin film 20 on the first surface s1 of the base substrate 10 and a part of the first conductive thin film 20 in the connection via hole 11 is thickened by an electroplating process to form a conductive film layer 200. FIG. 6 is a schematic diagram of an intermediate product formed in step S15 of the first example according to some embodiments of the present disclosure.

In some embodiments, step S15 includes placing the base substrate 10 on a carrier of an electroplating machine, pressing a powered-on pad, placing the base substrate in a via-filling electroplating bath (in which a dedicated via-filling electrolyte is used), and applying a current, and maintaining the electroplating solution in a continuous and rapid flow on the surface of the base substrate 10, such that cations in the electroplating solution on the sidewall of the connection via hole 11 acquire electrons, becoming atoms that deposit on the inner wall. Metal copper is mainly deposited (with a deposition rate of 0.5-3 um/min) in the first connection hole at a high speed using a specially formulated dedicated via-filling electrolyte, while the deposition rates of metal copper on the first surface s1 and the second surface s2 of the base substrate 10 are very small (0.005-0.05 um/min) as the two surfaces are flat areas. The metal copper on the sidewall of the connection via hole 11 grows thicker gradually over time.

In S16, the thickened first conductive thin film 20 on the first surface s1 of the base substrate 10 is removed, and at this point, the connection structure 23 disposed in the connection via hole 11 is formed as well as the signal wiring 21 and the connection pad 22 that are disposed on the second surface s2. FIG. 7 is a schematic diagram of an intermediate product formed in step S16 of the first example according to some embodiments of the present disclosure.

In some embodiments, a chemical mechanical polishing (CMP) method is adopted in S16 to remove the excess structure of the first conductive thin film 20 on the first surface s1. The seed layer disposed in the connection via hole 11 serves as the first substructure 231 of the connection structure 23, and the part of the thickened first conductive thin film 20 serves as the second substructure 232.

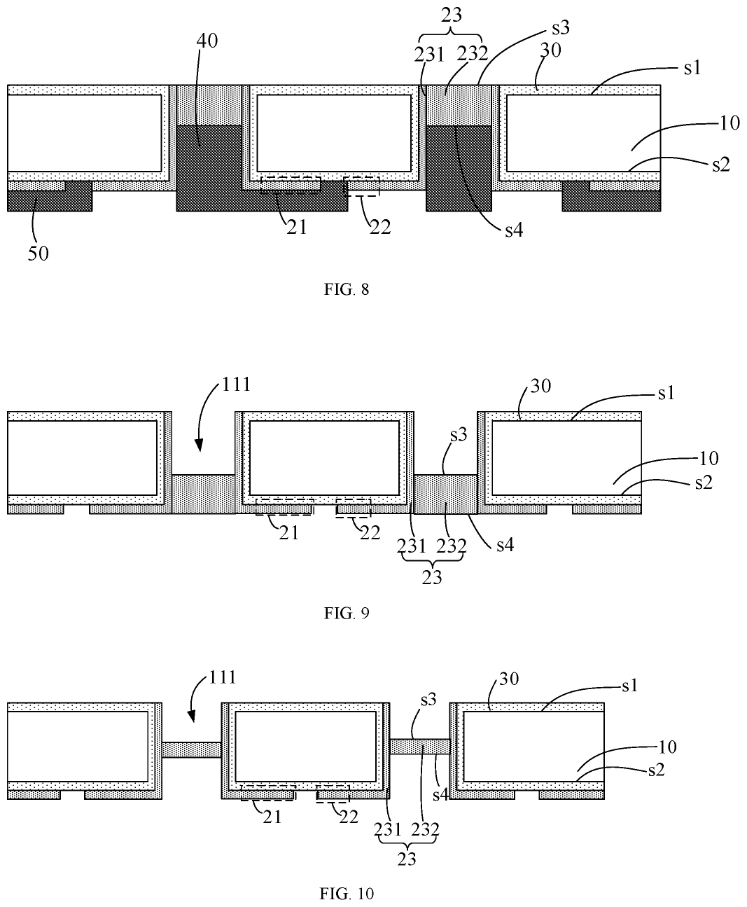

In S17, the filling structure 40 is filled in the accommodating space 111 defined by the formation of the connection structure 23 in the connection via hole 11. FIG. 8 is a schematic diagram of an intermediate product formed in step S17 of the first example according to some embodiments of the present disclosure.

In some embodiments, the second protection layer 50 covering the signal wiring 21 is further formed while filling the accommodating space 111. The filling structure 40 and the second protection layer 50 are an integral structure, and the material thereof includes, but is not limited to, a resin material.

In S18, a pixel drive circuit (thin-film transistor or the like), a light-emitting device, and the like are formed on the first surface s1 of the base substrate 10 following the completion of the above steps.

The pixel drive circuit and light-emitting device are formed by a method known in the related art, and thus the method will not be described in detail herein.

In the second example, FIG. 9 is a partial schematic diagram of the display substrate of the second example according to some embodiments of the present disclosure. As shown in FIG. 9, such display substrate is substantially the same as that of the first example, only except that the second substructure 232 of the connection structure 23 is close to the side of the second surface s2 of the base substrate 10 in this example. That is, the fourth surface s4 of the second substructure 232 is flush or substantially flush with the second surface s2 of the base substrate 10.

The method for manufacturing the display substrate of the second example is substantially the same as that of the first example, only except that when the connection structure 23 is formed by an electroplating process, the fourth surface s4 of the second substructure 232 is made flush or substantially flush with the second surface s2 of the base substrate 10 by controlling the process parameters. The remaining steps are the same as those of the first example and thus will not be repeated herein. It should be noted that, in the case that the connection pad 22 is formed on the second surface s2, the fourth surface s4 of the second substructure 232 is flush or substantially flush with the connection pad 22 disposed on the second surface s2 of the base substrate 10.

In the third example, FIG. 10 is a partial schematic diagram of the display substrate of the third example according to some embodiments of the present disclosure. As shown in FIG. 10, such display substrate is substantially the same as that of the first example, only except that the second substructure 232 of the connection structure 23 is disposed in the middle of the connection via hole 11 in this example, that is, a certain distance is reserved between the plane where the third surface s3 of the second substructure 232 is located and the plane where the first surface s1 of the base substrate 10 is located, and a certain distance is reserved between the plane where the fourth surface s4 of the second substructure 232 is located and the plane where the second surface s2 of the base substrate 10 is located.

The method for manufacturing the display substrate of the third example is substantially the same as that of the first example, only except that when the connection structure 23 is formed by an electroplating process, a certain distance is reserved between the plane where the third surface s3 of the second substructure 232 is located and the plane where the first surface s1 of the base substrate 10 is located, and a certain distance is reserved between the plane where the fourth surface s4 of the second substructure 232 is located and the plane of the second surface s2 of the base substrate 10 is located by controlling the process parameters. The remaining steps are the same as those of the first example and thus will not be repeated herein.

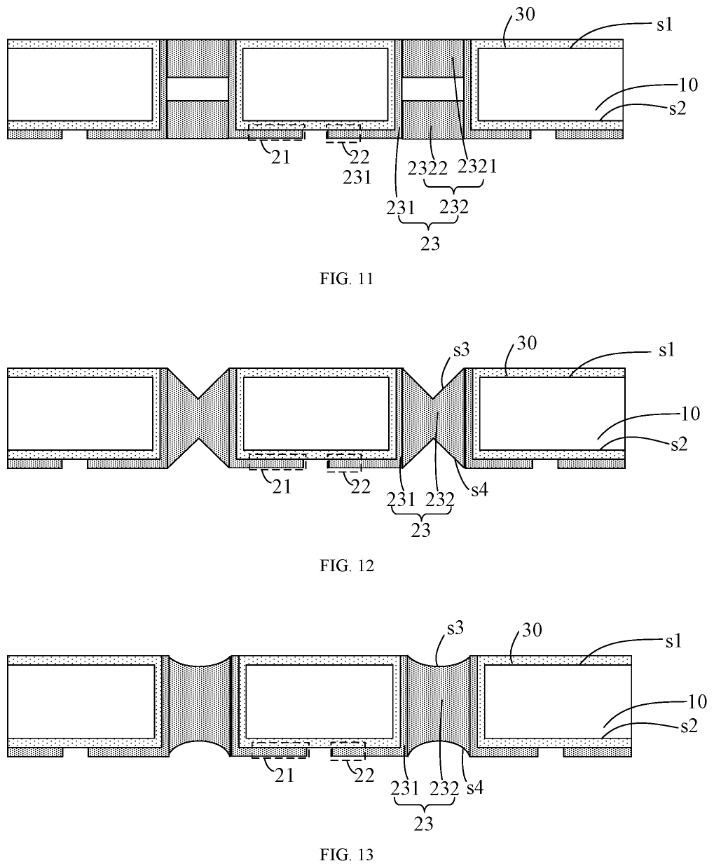

In the fourth example, FIG. 11 is a partial schematic diagram of the display substrate of the fourth example according to some embodiments of the present disclosure. As shown in FIG. 11, such display substrate is substantially the same as that of the first example, only except that the second substructure 232 of the connection structure 23 in this example includes a first portion 2321 and a second portion 2322; the outer outline of the first portion 2321 and the outer outline of the second portion 2322 both fit to the first substructure 231, and a certain distance is reserved between the first portion 2321 and the second portion 2322. Further, the surface of the first portion 2321 distal to the second portion 2322 is flush with the first surface s1. The surface of the second portion 2322 distal to the first portion 2321 is flush with the second surface s2.

In the fourth example, the distance between the first portion 2321 and the second portion 2322 of the first substructure 231 of the display substrate cannot be filled with the filling structure 40.

The method for manufacturing the display substrate of the fourth example is substantially the same as that of the first example, only except that when the connection structure 23 is formed by an electroplating process, the second substructure 232 composed of the first portion 2321 and the second portion 2322 is formed by controlling the process parameters. Alternatively, the first portion 2321 and the second portion 2322 of the second substructure 232 are formed through two electroplating processes. Only the parameters for the electroplating processes to be performed need to be controlled. The remaining steps are the same as those of the first example and thus will not be repeated herein. It should be noted that, in the case that the first protection layer 30 covers the first surface s1, the third surface s3 of the second substructure 232 is flush or substantially flush with the first protection layer 30 disposed on the first surface s1 of the base substrate 10; and in the case that the connection pad 22 is formed on the second surface s2, the fourth surface s4 of the second substructure 232 is flush or substantially flush with the connection pad 22 disposed on the second surface s2 of the base substrate 10.

In the fifth example, FIG. 12 is a partial schematic diagram of the display substrate of the fifth example according to some embodiments of the present disclosure. As shown in FIG. 12, such display substrate is substantially the same as that of the first example, only except that the third surface s3 of the second substructure 232 of the connection structure 23 in this example is folded and protrudes toward the fourth surface s4; and/or, the fourth surface s4 of the second substructure 232 is folded and protrudes toward the third surface s3.

The method for manufacturing the display substrate of the fifth example is substantially the same as that of the first example, only except that when the connection structure 23 is formed by an electroplating process, the third surface s3 and the fourth surface s4 of the second substructure 232 are formed into folded surfaces by controlling the process parameters. The remaining steps are the same as those of the first example and thus will not be repeated herein.

In the sixth example, FIG. 13 is a partial schematic diagram of the display substrate of the sixth example according to some embodiments of the present disclosure. As shown in FIG. 13, such display substrate is substantially the same as that of the first example, only except that the third surface s3 of the second substructure 232 of the connection structure 23 in this example is an arc surface and protrudes toward the fourth surface s4; and/or, the fourth surface s4 of the second substructure 232 is an arc surface and protrudes toward the third surface s3.

The method for manufacturing the display substrate of the sixth example is substantially the same as that of the first example, only except that when the connection structure 23 is formed by an electroplating process, the third surface s3 and the fourth surface s4 of the second substructure 232 are formed into arc surfaces by controlling the process parameters. The remaining steps are the same as those of the first example and thus will not be repeated herein.

It should be noted that, the above presents only a few exemplary structures of the display substrate. All modifications based on the above are within the protection scope of the embodiments of the present disclosure.

It can be understood that the above embodiments are merely exemplary embodiments employed to illustrate the principles of the present disclosure, and the present disclosure is not limited thereto. For those of ordinary skill in the art, various changes and modifications can be made without departing from the spirit and scope of the present disclosure, and these changes and modifications are also considered to fall within the protection scope of the present disclosure.

1. A display substrate, comprising:
a base substrate provided with a connection via hole penetrating in a thickness direction of the base substrate, wherein the base substrate comprises a first surface and a second surface disposed oppositely along the thickness direction of the base substrate;
a pixel drive circuit disposed on the first surface;
a signal wiring disposed on the second surface; and
a connection structure disposed in the connection via hole and electrically connecting the signal wiring with the pixel drive circuit, wherein the connection via hole is partially filled by the connection structure.

2. The display substrate according to claim 1, wherein the connection structure comprises a first substructure disposed on a sidewall of the connection via hole and a second substructure connected to the first substructure, with an outer outline of the second substructure fitted to the first substructure.

3. The display substrate according to claim 2, wherein the second substructure comprises a third surface and a fourth surface disposed oppositely along a thickness direction of the second substructure; there is one of:
the third surface being flush with the first surface, and a certain distance being reserved between a plane where the fourth surface is located and a plane where the second surface is located;
the fourth surface being flush with the second surface, and a certain distance being reserved between a plane where the third surface is located and a plane where the first surface is located; or,
a certain distance being reserved between the plane where the third surface is located and the plane where the first surface is located, and a certain distance being reserved between the plane where the fourth surface is located and the plane where the second surface is located.

4. The display substrate according to claim 2, wherein the second substructure comprises a first portion and a second portion, with an outer outline of the first portion and an outer outline of the second portion both fitted to the first substructure and a certain distance reserved between the first portion and the second portion.

5. The display substrate according to claim 4, wherein a surface of the first portion distal to the second portion is flush with the first surface; and a surface of the second portion distal to the first portion is flush with the second surface.

6. The display substrate according to claim 2, wherein the second substructure comprises a third surface and a fourth surface disposed oppositely along a thickness direction of the second substructure; there is at least one of:
the third surface being an arc surface and protrudes-protruding towards the fourth surface; or
the fourth surface being an arc surface and protruding towards the third surface.

7. The display substrate according to claim 2, wherein the second substructure comprises a third surface and a fourth surface disposed oppositely along a thickness direction of the second substructure; there is at least one of:
the third surface being folded and protruding towards the fourth surface; or
the fourth surface being folded and protruding towards the third surface.

8. The display substrate according to claim 1, wherein the connection structure is disposed in the connection via hole to define an accommodating space with a filling structure filled therein.

9. The display substrate according to claim 1, wherein a first protection layer is covered on a sidewall of the connection via hole, and the first protection layer is disposed between the sidewall of the connection via hole and the connection structure.

10. The display substrate according to claim 1, wherein a connection pad is further disposed on the second surface, and the signal wiring is electrically connected to the connection structure through the connection pad.

11. A method for manufacturing a display substrate, comprising:
providing a base substrate, wherein a connection via hole penetrating in a thickness direction of the base substrate is formed thereon, the base substrate comprises a first surface and a second surface disposed oppositely along the thickness direction of the base substrate;
forming a connection structure within the connection via hole of the base substrate, forming a pixel drive circuit on the first surface of the base substrate, and forming a signal wiring on the second surface of the base substrate, with the connection structure electrically connecting the signal wiring with the pixel drive circuit, wherein the connection structure does not fill the connection via hole completely.

12. The method according to claim 11, wherein the connection structure comprises a first substructure disposed on a sidewall of the connection via hole and a second substructure connected to the first substructure; and forming the connection structure comprises:
forming a first conductive thin film on the first surface, the second surface, and the sidewall of the connection via hole of the base substrate to serve as a seed layer, and performing electroplating and patterning processes in sequence to form the connection structure, wherein the seed layer disposed on the sidewall of the connection via hole serves as the first substructure, a structure of the seed layer disposed in the connection via hole and connected to the first substructure, serves as the second substructure.

13. The method according to claim 12, wherein the second substructure comprises a third surface and a fourth surface disposed oppositely along a thickness direction of the second substructure; there is one of:
the third surface being flush with the first surface, and a certain distance being reserved between a plane where the fourth surface is located and a plane where the second surface is located;
the fourth surface being flush with the second surface, and a certain distance being reserved between a plane where the third surface is located and a plane where the first surface is located; or,
a certain distance being reserved between the plane where the third surface is located and the plane where the first surface is located, and a certain distance being reserved between the plane where the fourth surface is located and the plane where the second surface is located.

14. The method according to claim 12, wherein the second substructure comprises a first portion and a second portion, with an outer outline of the first portion and an outer outline of the second portion both fitted to the first substructure and a certain distance reserved between the first portion and the second portion.

15. The method according to claim 14, wherein a surface of the first portion distal to the second portion is flush with the first surface; and a surface of the second portion distal to the first portion is flush with the second surface.

16. The method according to claim 12, wherein the second substructure comprises a third surface and a fourth surface disposed oppositely along a thickness direction of the second substructure; there is at least one of:
the third surface being an arc surface and protruding towards the fourth surface; or
the fourth surface being an arc surface and protruding towards the third surface.

17. The method according to claim 12, wherein the second substructure comprises a third surface and a fourth surface disposed oppositely along a thickness direction of the second substructure; there is at least one of:
the third surface being folded and protruding towards the fourth surface; or
the fourth surface being folded and protruding towards the third surface.

18. The method according to claim 11, further comprising filling a filling structure in an accommodating space defined by forming the connection structure in the connection via hole.

19. The method according to claim 11, further comprising forming a first protection layer on at least a sidewall of the connection via hole before forming the connection via hole.

20. The method according to claim 11, further comprising forming a connection pad on the second surface, wherein the signal wiring is electrically connected to the connection structure through the connection pad.
